(19) United States
(12) Patent Application Publication
(10) Pub. No.: US 2024/0250162 A1
(43) Pub. Date: Jul. 25, 2024

(54) SEMICONDUCTOR DEVICE

(71) Applicant: Japan Display Inc., Tokyo (JP)

(72) Inventors: Hiroumi KINJO, Tokyo (JP); Masumi NISHIMURA, Tokyo (JP); Hayata AOKI, Tokyo (JP)

(73) Assignee: Japan Display Inc., Tokyo (JP)

(21) Appl. No.: 18/397,224

(22) Filed: Dec. 27, 2023

Related U.S. Application Data
(63) Continuation of application No. PCT/JP2022/022888, filed on Jun. 7, 2022.

(30) Foreign Application Priority Data
Jun. 29, 2021 (JP) 2021-108107

(51) Int. Cl. H01L 29/778; H01L 27/15; H01L 29/20; H01L 33/32; H01L 33/58

(52) U.S. Cl. CPC H01L 29/7786; H01L 27/15; H01L 29/2003; H01L 33/32; H01L 33/58

(57) ABSTRACT

A semiconductor device using a gallium nitride layer has an amorphous glass substrate, an oriented insulating layer arranged on the amorphous glass substrate and having a crystal orientation, a first gallium nitride layer arranged on the oriented insulating layer and in contact with the oriented insulating layer, the first gallium nitride layer being a first conductivity type, a gate electrode opposed to the first gallium nitride layer, and a gate insulating layer between the first gallium nitride layer and the gate electrode. The oriented insulating layer may have a plane with 6-fold rotational symmetry.

### CROSS REFERENCE TO RELATED APPLICATIONS

This application is a Continuation of International Patent Application No. PCT/JP2022/022888, filed on Jun. 7, 2022, which claims the benefit of priority to Japanese Patent Application No. 2021-108107 filed on Jun. 29, 2021, the entire contents of which are incorporated herein by reference.

### FIELD

An embodiment of the present invention relates to a semiconductor device using gallium nitride.

### BACKGROUND

Gallium nitride (GaN) is a direct-transition semiconductor with a large bandgap. A light-emitting diode (LED) including gallium nitride has been put into practical use by using the characteristics of gallium nitride. Gallium nitride is characterized by high electron saturation mobility and pressure resistance. In recent years, a transistor (semiconductor device) has been developed for use in a high-frequency power device or the like by utilizing the characteristics of gallium nitride. Generally, gallium nitride layers used in light-emitting diodes or transistors are deposited on sapphire substrates at high temperatures of 800° C. to 1000° C. using MOCVD (Metal Organic Chemical Vapor Deposition) or HVPE (Hydride Vapor Phase Epitaxy).

Furthermore, in recent years, so-called micro LED display devices or mini LED display devices in which small light-emitting diode chips are mounted in pixels of a circuit board have been developed as next-generation representative devices. The micro LED display devices or the mini LED display devices have high efficiency, high brightness, and high reliability. Such micro LED display devices or mini LED display devices are manufactured by transferring a LED tip to a backplane in which a transistor including low-temperature polysilicon, or an oxide semiconductor and the like is formed (for example, see U.S. Pat. No. 8,791,474). On the other hand, a method for forming a transistor including gallium nitride and a light-emitting diode on the same substrate has also been studied (see, for example, U.S. Patent Application Publication No. 2020/0075664).

### SUMMARY

A semiconductor device according to an embodiment of the present invention includes an amorphous glass substrate, an oriented insulating layer arranged on the amorphous glass substrate and having a crystal orientation, a first gallium nitride layer arranged on the oriented insulating layer and in contact with the oriented insulating layer, the first gallium nitride layer being a first conductivity type, a gate electrode opposed to the first gallium nitride layer, and a gate insulating layer between the first gallium nitride layer and the gate electrode.

A semiconductor device according to an embodiment of the present invention includes an amorphous glass substrate, a gate electrode arranged on the amorphous glass substrate, a gate insulating layer arranged on the gate electrode and having a crystal orientation, and a first gallium nitride layer arranged on the gate insulating layer and in contact with the gate insulating layer, the first gallium nitride layer being a first conductivity type.

### BRIEF DESCRIPTION OF DRAWINGS

FIG. 1 is a cross-sectional view showing a configuration of a semiconductor device according to an embodiment of the present invention.

FIG. 2 is a cross-sectional view showing a configuration of a semiconductor device according to an embodiment of the present invention.

FIG. 3 is a cross-sectional view showing a configuration of a semiconductor device according to an embodiment of the present invention.

FIG. 4 is a cross-sectional view showing a configuration of a semiconductor device according to an embodiment of the present invention.

FIG. 5 is a cross-sectional view showing a configuration of a semiconductor device according to an embodiment of the present invention.

FIG. 6 is a cross-sectional view showing a configuration of a semiconductor device according to an embodiment of the present invention.

FIG. 7 is a cross-sectional view showing a configuration of a semiconductor device according to an embodiment of the present invention.

FIG. 8 is a cross-sectional view showing a configuration of a semiconductor device according to an embodiment of the present invention.

FIG. 9 is a cross-sectional view showing a configuration of a semiconductor device according to an embodiment of the present invention.

FIG. 10 is a cross-sectional view showing a configuration of a semiconductor device according to an embodiment of the present invention.

FIG. 11 is a cross-sectional view showing a configuration of a semiconductor device according to an embodiment of the present invention.

FIG. 12 is a cross-sectional view showing a configuration of a semiconductor device according to an embodiment of the present invention.

FIG. 13 is a cross-sectional view showing a configuration of a semiconductor device according to an embodiment of the present invention.

FIG. 14 is a cross-sectional view showing a configuration of a semiconductor device according to an embodiment of the present invention.

FIG. 15 is a schematic diagram showing a configuration of a display device according to an embodiment of the present invention.

FIG. 16 is a circuit diagram (pixel circuit) of a pixel of a display device according to an embodiment of the present invention.

FIG. 17 is a cross-sectional view of a pixel of a display device according to an embodiment of the present invention.

### DESCRIPTION OF EMBODIMENTS

Hereinafter, embodiments of the present invention will be described with reference to the drawings. The following disclosure is merely an example. A configuration that can be easily conceived by a person skilled in the art by appropriately changing the configuration of the embodiment while keeping the gist of the invention is naturally included in the scope of the present invention. In the drawings, the widths, thicknesses, shapes, and the like of the respective portions may be schematically represented in comparison with actual embodiments for clarity of explanation. However, the shown shapes are merely examples, and do not limit the interpretation of the present invention. In the present specification and the drawings, elements similar to those described above with respect to the drawings described above are denoted by the same reference symbols, and a detailed description thereof may be omitted as appropriate.

In each embodiment of the present invention, a direction from a substrate toward a gate electrode is referred to as “upper” or “above”. Conversely, a direction from the gate electrode toward the substrate is referred to as “lower” or “below”. As described above, although the term “above” or “below” is used to for convenience of explanation, for example, the substrate and the gate electrode may be arranged such that a vertical relationship between the substrate and the gate electrode is opposite to that shown in the drawing. In the following description, for example, the expression “gate electrode above the substrate” merely describes the vertical relationship between the substrate and the gate electrode as described above, and other members may be disposed between the substrate and the gate electrode. “Above” or “below” means a stacking order in a structure in which a plurality of layers are stacked, and in the case where the stacking order is expressed as a pixel electrode above the transistor, a positional relationship may be such that the transistor and the pixel electrode do not overlap each other in a plan view. On the other hand, the expression “pixel electrode vertically above the transistor” means a positional relationship in which the transistor and the pixel electrode overlap in a plan view.

As used herein, the phrase “α comprises A, B or C,” “α comprises any of A, B or C,” “α comprises one selected from the group consisting of A, B and C,” and the like does not exclude cases where α comprises a plurality of combinations of A to C unless otherwise indicated. Furthermore, these expressions do not exclude the case where a includes other elements.

The following embodiments can be combined with each other as long as there is no technical inconsistency.

Manufacturing methods of micro LED display devices by a transfer of LED tips have high manufacturing costs, and it is difficult to manufacture the micro LED display devices at low cost. If a transistor using gallium nitride can be formed together with a light-emitting diode on a large-area substrate such as an amorphous glass substrate, the manufacturing cost can be reduced. However, since the gallium nitride layer is formed at a high temperature as described above, it is difficult to directly form the transistor including gallium nitride on the amorphous glass substrate.

An object of an embodiment of the present invention is to provide a semiconductor device using a gallium nitride layer.

### 1. First Embodiment

### [1-1. Configuration of Semiconductor Device 10]

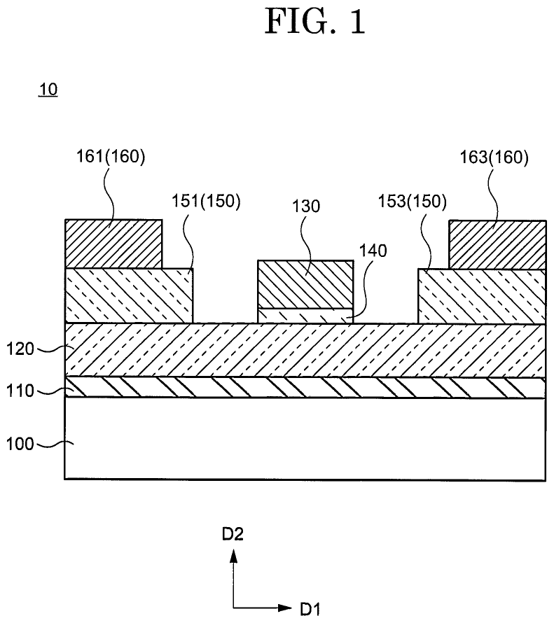

A semiconductor device 10 according to a first embodiment of the present invention will be described with reference to FIG. 1. FIG. 1 is a cross-sectional view showing a configuration of a semiconductor device according to an embodiment of the present invention. As shown in FIG. 1, the semiconductor device 10 includes a substrate 100, an oriented insulating layer 110, a first gallium nitride layer 120, a gate electrode 130, a gate insulating layer 140, a second gallium nitride layer 150 (151, 153), and an electrode 160 (161, 163).

The substrate 100 is an amorphous substrate. For example, the substrate 100 is an amorphous glass substrate. However, the substrate 100 may be a resin substrate. As the resin substrate, a flexible substrate such as a polyimide substrate, an acrylic substrate, a siloxane substrate, or a fluororesin substrate is used.

The oriented insulating layer 110 is arranged on the substrate 100. The oriented insulating layer 110 has a crystal orientation (for example, c-axis orientation). Specifically, a surface of the oriented insulating layer 110 is a plane with 6-fold rotational symmetry. For example, the oriented insulating layer 110 has a (0001) plane in a hexagonal close-packed structure or a (111) plane in a face-centered cubic structure. For example, aluminum nitride, gallium oxide, or titanium oxide is used as the oriented insulating layer 110. Since the oriented insulating layer 110 has the characteristics described above, a gallium nitride layer having high crystallinity can be obtained in the case where the gallium nitride layer is grown on the oriented insulating layer 110. For example, in the case where the oriented insulating layer 110 is c-axis oriented with respect to the substrate 100, a c-axis oriented gallium nitride layer is grown on the oriented insulating layer 110. For example, the oriented insulating layer 110 is formed by a sputtering method.

However, the oriented insulating layer 110 is not limited to the configuration described above. For example, the oriented insulating layers 110 may be formed by a method other than physical vapor deposition (PVD) method. For example, the oriented insulating layer 110 may be formed by a vacuum deposition method or an electron beam deposition method. The oriented insulating layers 110 may be formed by chemical vapor deposition (CVD) method. A heat CVD method, a plasma CVD method, a catalytic CVD method (Cat(Catalytic)-CVD method or hot wire CVD method), and the like are used as CVD methods. An underlying insulating layer may be arranged between the substrate 100 and the oriented insulating layer 110. As the underlying insulating layer, a silicon oxide layer, a silicon nitride layer, an aluminum oxide layer, an aluminum nitride layer, and a stack thereof are used. For example, a stack of [silicon nitride layer/silicon oxide layer/silicon nitride layer] may be used as the underlying insulating layer.

The first gallium nitride layer 120 is in contact with the oriented insulating layer 110 from above the oriented insulating layer 110. For example, the first gallium nitride layer 120 is formed by the sputtering method. Crystal growth of the first gallium nitride layer 120 is controlled by the oriented insulating layer 110. As a result, the first gallium nitride layer 120 has crystallinity (or orientation) reflecting crystallinity (or orientation) of the oriented insulating layer 110. As described above, in the case where the oriented insulating layer 110 is c-axis-oriented, the c-axis-oriented first gallium nitride layer 120 is obtained.

For example, the first gallium nitride layer 120 is a p-type gallium nitride layer. In this case, for example, a gallium nitride layer doped with magnesium or selenium is used as the first gallium nitride layer 120.

The gate electrode 130 is arranged on the first gallium nitride layer 120 and faces the first gallium nitride layer 120. The gate insulating layer 140 is arranged between the first gallium nitride layer 120 and the gate electrode 130. The gate insulating layer 140 is in contact with each of the first gallium nitride layer 120 and the gate electrode 130. A general metal is used as the gate electrode 130. For example, aluminum, titanium, platinum, nickel, tantalum, and alloys thereof are used as the gate electrode 130 in a single layer or stacked layers. A metal oxide, a metal nitride, or an organic material is used as the gate insulating layer 140. For example, a silicon oxide layer, a silicon nitride layer, an aluminum oxide layer, an aluminum nitride layer, gallium oxide, titanium oxide, titanium nitride, and a stack thereof are used as the gate insulating layer 140. In the case where the semiconductor device 10 is configured to use a Schottky barrier at an interface between the first gallium nitride layer 120 and the gate electrode 130, the gate insulating layer 140 may be omitted.

The second gallium nitride layer 150 is in contact with the first gallium nitride layer 120 from above the first gallium nitride layer 120. The second gallium nitride layer 150 includes a source-side second gallium nitride layer 151 arranged on a source-side of the semiconductor device 10 and a drain-side second gallium nitride layer 153 arranged on a drain-side of the semiconductor device 10. The source-side second gallium nitride layer 151 and the drain-side second gallium nitride layer 153 are separated from each other, and the gate electrode 130 is arranged therebetween. Conductivity of the second gallium nitride layer 150 is higher than conductivity of the first gallium nitride layer 120. That is, electrical resistivity of the second gallium nitride layer 150 is lower than electrical resistivity of the first gallium nitride layer 120.

The second gallium nitride layer 150 is formed by the sputtering method in the same manner as the first gallium nitride layer 120. Crystal growth of the second gallium nitride layer 150 is controlled by the first gallium nitride layer 120. As a result, the second gallium nitride layer 150 has crystallinity (or orientation) reflecting the crystallinity (or orientation) of the first gallium nitride layer 120. As described above, in the case where the first gallium nitride layer 120 is c-axis oriented, the c-axis oriented second gallium nitride layer 150 is obtained.

The second gallium nitride layer 150 is, for example, an n-type gallium nitride layer. In this case, for example, a gallium nitride layer doped with silicon or germanium is used as the second gallium nitride layer 150. In the present embodiment, although a configuration in which the first gallium nitride layer 120 has p-type conductivity and the second gallium nitride layer 150 has n-type conductivity has been exemplified, the configuration is not limited to this configuration. The first gallium nitride layer 120 may have n-type conductivity, and the second gallium nitride 20) layer 150 may have p-type conductivity. As a representation including the above two configurations, the first gallium nitride layer 120 may have a first conductivity type and the second gallium nitride layer 150 may have a second conductivity type.

Since the first gallium nitride layer 120 and the second gallium nitride layer 150 are formed by the sputtering method, a process gas used in a sputtering process remains in these gallium nitride layers. For example, in the case where argon gas is used in the sputtering process for forming the first gallium nitride layer 120 and the second gallium nitride layer 150, the gallium nitride layers include argon. For example, the argon gas can be detected by analytical methods such as secondary ion-mass spectrometry (SIMS) for these gallium nitride layers.

The electrode 160 is in contact with the second gallium nitride layer 150 from above the second gallium nitride layer 150. The electrode 160 includes a source-side electrode 161 arranged on the source-side of the semiconductor device 10 and a drain-side electrode 163 arranged on the drain-side of the semiconductor device 10. The source-side electrode 161 is connected to the source-side second gallium nitride layer 151. The drain-side electrode 163 is connected to the drain-side second gallium nitride layer 153. A common metal is used as the electrode 160. For example, aluminum, titanium, platinum, nickel, tantalum, and alloys thereof are used as the electrode 160 in a single layer or stacked layers.

When a predetermined voltage (ON voltage) is supplied to the gate electrode 130, carriers are generated in the first gallium nitride layer 120 (channel is formed) in a vicinity of an interface between the first gallium nitride layer 120 and the gate insulating layer 140. In this state, a potential difference is applied between the source-side second gallium nitride layer 151 and the drain-side second gallium nitride layer 153, so that a current flows from the source-side second gallium nitride 20) layer 151 to the drain-side second gallium nitride layer 153 through the channel.

### [1-2. Method for Manufacturing Semiconductor Device 10]

The oriented insulating layer 110 is formed on the substrate 100 which is the amorphous glass substrate. For example, the oriented insulating layer 110 is formed by sputtering as described above. The first gallium nitride layer 120 and the second gallium nitride layer 150 are formed on the oriented insulating layer 110. For example, these gallium nitride layers are formed by the sputtering method. Formation of the oriented insulating layer 110, the first gallium nitride layer 120, and the second gallium nitride layer 150 is preferably performed continuously. For example, the formation of these layers may be performed in a sputtering apparatus provided with a plurality of chambers for forming the respective layers while being held in a vacuum. Contamination at the interface between the oriented insulating layer 110 and the first gallium nitride layer 120, and at the interface between the first gallium nitride layer 120 and the second gallium nitride layer 150 can be reduced by forming the layer described above, and defects in the first gallium nitride layer 120 and the second gallium nitride layer 150 can be reduced. As a result, good crystallinity can be obtained for each of the first gallium nitride layer 120 and the second gallium nitride layer 150.

Subsequently, as shown in FIG. 1, the second gallium nitride layer 150 formed later in a region where the gate electrode 130 and the gate insulating layer 140 are arranged is removed, and the first gallium nitride layer 120 in the region is exposed.

Subsequently, the gate insulating layer 140 and the gate electrode 130 are formed. The gate insulating layer 140 and the gate electrode 130 are formed on each of the first gallium nitride layer 120 and the second gallium nitride layer 150. Thereafter, as shown in FIG. 1, the gate insulating layer 140 and the gate electrode 130 are patterned. Subsequently, the electrode 160 is formed on an entire surface and patterned as shown in FIG. 1.

As described above, since the formation of the oriented insulating layer 110, the first gallium nitride layer 120, and the second gallium nitride layer 150 is continuously performed, good crystallinity can be obtained for each of the first gallium nitride layer 120 and the second gallium nitride layer 150.

Although a manufacturing method in which the electrode 160 is formed after the gate insulating layer 140 and the gate electrode 130 are patterned has been exemplified above, the manufacturing method is not limited to this manufacturing method. For example, the electrode 160 may be formed immediately after the second gallium nitride layer 150 is formed, and the gate insulating layer 140 and the gate electrode 130 may be patterned after the patterning of the electrode 160 and the patterning of the second gallium nitride layer 150 are performed.

### [1-3. Method for Depositing First Gallium Nitride Layer 120 and Second Gallium Nitride Layer 150]

Deposition of the gallium nitride layer using sputtering will be described.

The substrate 100 such as the amorphous glass substrate is disposed in a vacuum chamber of the sputtering apparatus at a position facing a gallium nitride target. The composition ratio of gallium nitride in the gallium nitride target is preferably 0.7 or more and 2 or less in terms of ratio of gallium to nitrogen. The vacuum chamber is supplied with nitrogen gas in addition to a sputtering gas (such as argon or krypton). In this case, the composition ratio of gallium nitride in the gallium nitride target is preferably a gallium-rich ratio over nitrogen. For example, the nitrogen may be supplied by a nitrogen radical source. A sputtering power supply may be a DC power supply, an RF power supply, or a pulsed DC power supply.

The substrate 100 may be heated in the vacuum chamber. For example, the substrate 100 may be heated at 400° C. or more and 600° C. or less. At this heating temperature, a heat treatment can be applied to an amorphous glass substrate having low heat resistance. This heating temperature is lower than the heating temperature of the metal organic vapor deposition (MOCVD) or the hydride vapor phase epitaxy (HVPE).

The sputtering gas is supplied after the vacuum chamber in which the substrate 100 is arranged is sufficiently evacuated. A gallium nitride layer is formed by applying a voltage between the substrate 100 and the gallium nitride target at a predetermined pressure to generate a plasma.

The configuration of the sputtering apparatus or sputtering conditions can be appropriately changed. An aluminum gallium nitride layer can be formed if an aluminum gallium nitride target is used instead of the gallium nitride target.

### 2. Second Embodiment

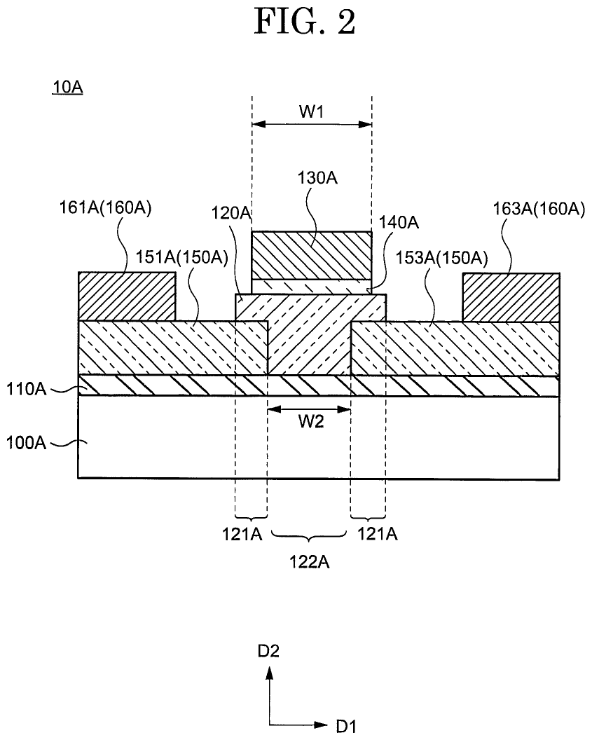

Referring to FIG. 2, a semiconductor device 10A according to a second embodiment of the present disclosure will be described. The semiconductor device 10A is similar to the semiconductor device 10 according to the first embodiment.

Descriptions of the same configuration as that of the semiconductor device 10 of the first embodiment in a configuration of the semiconductor device 10A are omitted, and differences from the semiconductor device 10 will be mainly described in the following description. In the case of describing the same configuration as in the first embodiment in the following explanation, with reference to FIG. 1, the letter “A” is added after the reference symbols shown in FIG. 1.

### [2-1. Configuration of Semiconductor Device 10A]

As shown in FIG. 2, a second gallium nitride layer 150A (151A, 153A) is in contact with an oriented insulating layer 110A from above the oriented insulating layer 110A. The second gallium nitride layer 150A is separated into a source-side second gallium nitride layer 151A and a drain-side second gallium nitride layer 153A. A first gallium nitride layer 120A is arranged on the second gallium nitride layer 150A and on the oriented insulating layer 110A exposed from the second gallium nitride layer 150A. The first gallium nitride layer 120A is in contact with the second gallium nitride layer 150A from above the second gallium nitride layer 150A in a first region 121A. The first gallium nitride layer 120A is in contact with the oriented insulating layer 110A from above the oriented insulating layer 110A in a second region 122A. In other words, the first gallium nitride layer 120A is arranged so as to fill an opening arranged between the source-side second gallium nitride layer 151A and the drain-side second gallium nitride layer 153A.

A gate electrode 130A and a gate insulating layer 140A are arranged in a region corresponding to the second region 122A. As shown in FIG. 2, a width W1 of the gate electrode 130A is larger than a distance W2 between the source-side second gallium nitride layer 151A and the drain-side second gallium nitride layer 153A in a direction D1. In other words, the distance W2 between a source electrode (the source-side second gallium nitride layer 151A) and a drain electrode (the drain-side second gallium nitride layer 153A) of the semiconductor device 10A is smaller than the width W1 of the gate electrode 130A in the direction D1.

In FIG. 2, although an upper surface of the first gallium nitride layer 120A is flat, the configuration is not limited to this. For example, the upper surface of the first gallium nitride layers 120A may be recessed in a region corresponding to the second region 122A.

### [2-2. Method for Manufacturing Semiconductor Device 10A]

As shown in FIG. 2, the oriented insulating layer 150A is formed on the second gallium nitride layer 110A, the second gallium nitride layer 150A in the second region 122A is removed, and the oriented insulating layer 110A in the second region 122A is exposed. The first gallium nitride layer 120A is formed over the exposed oriented insulating layer 110A and over the second gallium nitride layer 150A. Subsequently, the gate insulating layer 140A and the gate electrode 130A are formed on the first gallium nitride layer 120A. Thereafter, the gate insulating layer 140A, the gate electrode 130A, and the first gallium nitride layer 120A are patterned as shown in FIG. 2. Finally, an electrode 160A is patterned.

As described above, contamination at an interface between the first gallium nitride layer 120A and the gate insulating layer 140A can be reduced, and defects in an upper portion (region where channel is formed) of the first gallium nitride layer 120A can be reduced because the first gallium nitride layer 120A, the gate insulating layer 140A, and the gate electrode 130A are continuously formed. As a consequence, good electric properties of the semiconductor device 10A can be obtained.

### 3. Third Embodiment

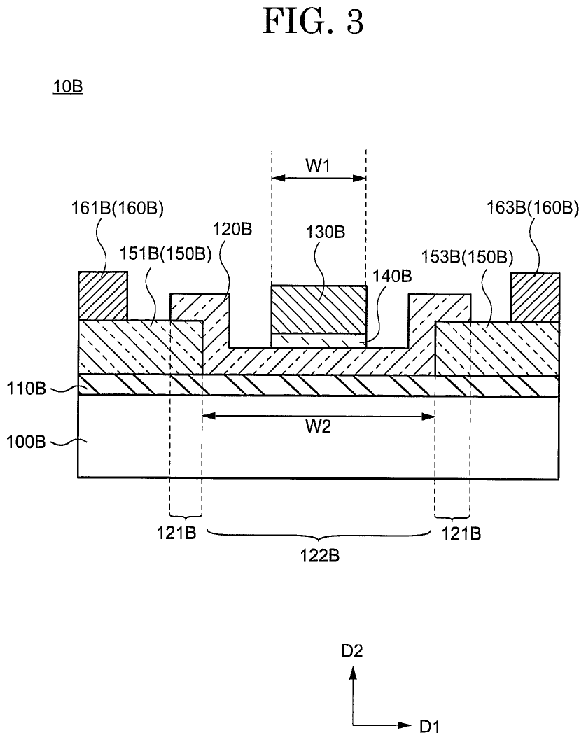

Referring to FIG. 3, a semiconductor device 10B according to a third embodiment of the present disclosure will be described. The semiconductor device 10B is similar to the semiconductor device 10A according to the second embodiment. Differences from the semiconductor device 10A in a configuration of the semiconductor device 10B will be mainly described in the following explanation. In the case of describing the same configuration as the above embodiment in the following explanation, with reference to FIG. 1, the letter “B” is added after the reference symbols shown in FIG. 1.

### [3-1. Configuration of Semiconductor Device 10B]

As shown in FIG. 3, a width W1 of a gate electrode 130B is smaller than a width W2 of a second region 122B in the direction D1. In the second regions 122B, a recess is formed in an upper surface of a first gallium nitride layer 120B. A gate insulating layer 140B and the gate electrode 130B are arranged in the recess. In FIG. 3, since a film thickness of the first gallium nitride layer 120B is smaller than a film thickness of a second gallium nitride layer 150B, an upper surface of the second gallium nitride layer 150B is located above a lower surface of the gate insulating layer 140B in the direction D2.

According to the semiconductor device 10B of the third embodiment, the same effects as those of the semiconductor device 10A of the second embodiment can be obtained.

### 4. Fourth Embodiment

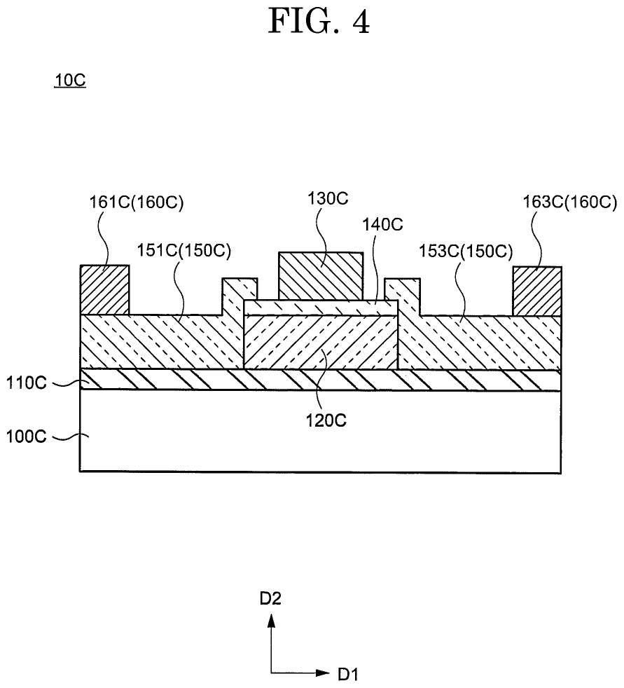

Referring to FIG. 4, a semiconductor device 10C according to a fourth embodiment of the present disclosure will be described. The semiconductor device 10C is similar to the semiconductor device 10A according to the second embodiment. Differences from the semiconductor device 10A in a configuration of the semiconductor device 10C will be mainly described in the following explanation. In the case of describing the same configuration as the above embodiment in the following explanation, with reference to FIG. 1, the letter “C” is added after the reference symbols shown in FIG. 1.

### [4-1. Configuration of Semiconductor Device 10C]

As shown in FIG. 4, a first gallium nitride layer 120C and a gate insulating layer 140C are arranged on an oriented insulating layer 110C. The first gallium nitride layer 120C is in contact with the oriented insulating layer 110C. In a region where the first gallium nitride layer 120C is not arranged, a second gallium nitride layer 150C is arranged on the oriented insulating layer 110C. The second gallium nitride layer 150C is in contact with the oriented insulating layer 110C. The second gallium nitride layer 150C rides on patterned end portions of the first gallium nitride layer 120C and the gate insulating layer 140C, and is also arranged on the gate insulating layer 140C. That is, a portion of the second gallium nitride layer 150C is in contact with the gate insulating layer 140C from above the gate insulating layer 140C. The second gallium nitride layer 150C is in contact with the first gallium nitride layer 120C at a sidewall of the first gallium nitride layer 120C. A gate electrode 130C is arranged on the gate insulating layer 140C in a region between a source-side second gallium nitride layer 151C and a drain-side second gallium nitride layer 153C.

### [4-2. Method for Manufacturing Semiconductor Device 10C]

The first gallium nitride layer 120C and the gate insulating layer 140C are continuously formed on the oriented insulating layer 110C. Thereafter, the first gallium nitride layer 120C and the gate insulating layer 140C are collectively patterned. Subsequently, the second gallium nitride layer 150C is formed on the oriented insulating layer 110C and the gate insulating layer 140C, and is patterned as shown in FIG. 4. The gate insulating layer 140C between the source-side second gallium nitride layer 151C and the drain-side second gallium nitride layer 153C is exposed by the patterning. The gate electrode 130C is formed on the exposed gate insulating layers 140C. Finally, an electrode 160C is patterned.

As described above, in the semiconductor device 10C of the present embodiment, the oriented insulating layer 110C, the first gallium nitride layer 120C, and the gate insulating layer 140C are continuously formed. As a consequence, good crystallinity of the first gallium nitride layer 120C can be obtained, contamination at an interface between the first gallium nitride layer 120C and the gate insulating layer 140C can be reduced, and defects in an upper portion (region where channel is formed) of the first gallium nitride layer 120C can be reduced.

### [4-3. Modification of Third Embodiment]

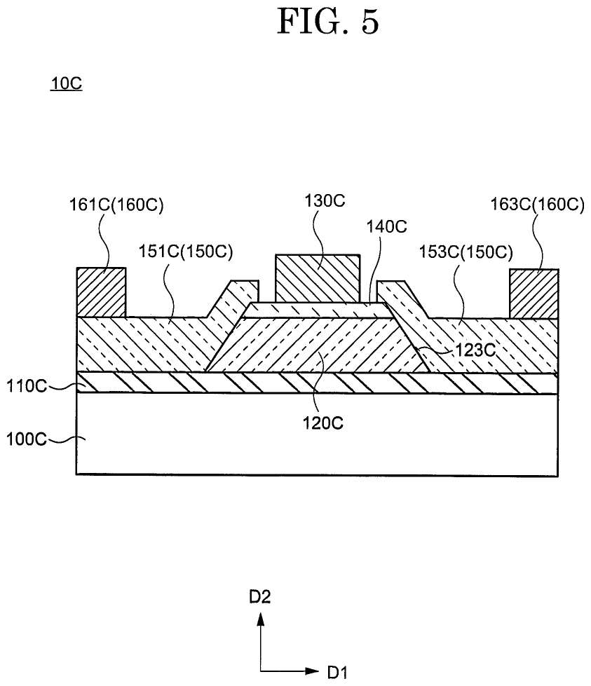

As shown in FIG. 5, a sidewall 123C of the first gallium nitride layers 120C may be tapered. Since the sidewall 123C is tapered, the first gallium nitride layer 120C and the second gallium nitride layer 150C can be easily made to contact each other. As a consequence, it is possible to avoid conduction failure between the first gallium nitride layer 120C and the second gallium nitride layer 150C.

Although FIG. 5 shows a configuration in which a taper angle of the sidewall 123C of the first gallium nitride layer 120C and a taper angle of a sidewall of the gate insulating layer 140C are at the same angle, the configuration is not limited to this configuration. For example, the taper angle of the side wall of the gate insulating layer 140C may be smaller than or larger than the taper angle of the side wall 123C. The patterned end portion of the gate insulating layer 140C may be retracted to expose an upper surface of the first gallium nitride layer 120C.

### 5. Fifth Embodiment

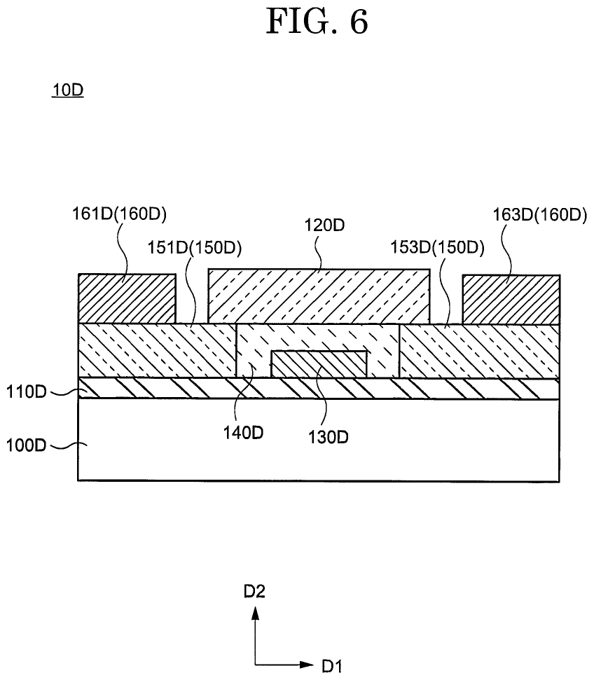

Referring to FIG. 6, a semiconductor device 10D according to a fifth embodiment of the present disclosure will be described. The semiconductor device 10D is similar to the semiconductor device 10A according to the second embodiment. Differences from the semiconductor device 10A in a configuration of the semiconductor device 10D will be mainly described in the following explanation. In the case of describing the same configuration as the above embodiment in the following explanation, with reference to FIG. 1, the letter “D” is added after the reference symbols shown in FIG. 1.

### [5-1. Configuration of Semiconductor Device 10D]

As shown in FIG. 6, a gate electrode 130D is arranged on oriented insulating layers 110D. In other words, the oriented insulating layers 110D are arranged between a substrate 100D and the gate electrode 130D. Gate insulating layers 140D are arranged on the gate electrodes 130D. The gate electrode 130D and the gate insulating layer 140D are in contact with the oriented insulating layer 110D. The gate insulating layer 140D is patterned, and a portion of the oriented insulating layer 110D is exposed from the gate insulating layer 140D. A second gallium nitride layer 150D is in contact with the oriented insulating layer 110D from above the exposed oriented insulating layer 110D. A first gallium nitride layer 120D is arranged on the gate insulating layer 140D and the second gallium nitride layer 150D. The second gallium nitride layer 150D is in contact with the first gallium nitride layer 120D from below the first gallium nitride layer 120D.

In the present embodiment, the gate electrode 130D and the gate insulating layer 140D have crystalline orientations (for example, c-axis orientation). Specifically, surfaces of the gate electrodes 130D and the gate insulating layers 140D are planes having 6-fold rotational symmetry. For example, the gate electrode 130D and the gate insulating layer 140D have (0001) planes in a hexagonal close-packed structure or (111) planes in a face-centered cubic structure. For example, titanium or aluminum is used as the gate electrode 130D. For example, aluminum-nitride, gallium-oxide, or titanium-oxide is used as the gate insulating layer 140D.

In FIG. 6, although a configuration is shown in which a height of the gate insulating layer 140D and a height of the second gallium nitride layer 150D coincide with each other in the direction D2, the configuration is not limited to this configuration. For example, the height of the gate insulating layer 140D may be larger than the height of the second gallium nitride layer 150D in the direction D2. In this case, a portion of the gate-insulating layer 140D may be arranged on the second gallium nitride layer 150D. Conversely, the height of the gate insulating layer 140D may be smaller than the height of the second gallium nitride layer 150D in the direction D2. In this case, a portion of the second gallium nitride layer 150D may be arranged on the gate insulating layer 140D.

Since the second gallium nitride layer 150D is arranged on the oriented insulating layer 110D as described above, good crystallinity can be obtained for the second gallium nitride layer 150. Similarly, since the gate electrode 130D and the gate insulating layer 140D having crystal orientation are arranged on the oriented insulating layer 110D and the first gallium nitride layer 120D is arranged on the gate insulating layer 140D, good crystallinity can be obtained for the first gallium nitride layer 120D.

### [5-2. Method for Manufacturing Semiconductor Device 10D]

The gate electrode 130D is formed on the oriented insulating layers 110D and patterned as shown in FIG. 6. The gate insulating layer 140D is formed on the patterned gate electrode 130D and patterned as shown in FIG. 6. Subsequently, the second gallium nitride 150D is formed and patterned as shown in FIG. 6. The first gallium nitride layer 120D is formed on the gate insulating layer 140D and the second gallium nitride layer 150D and patterned. Finally, an electrode 160D is patterned.

Although a manufacturing method in which the gate electrode 130D and the gate insulating layer 140D are formed and then the second gallium nitride layer 150D is formed has been exemplified in the present embodiment, a manufacturing method in which the gate electrode 130D and the gate insulating layer 140D are formed after the second gallium nitride layer 150D is formed may be used.

### 6. Sixth Embodiment

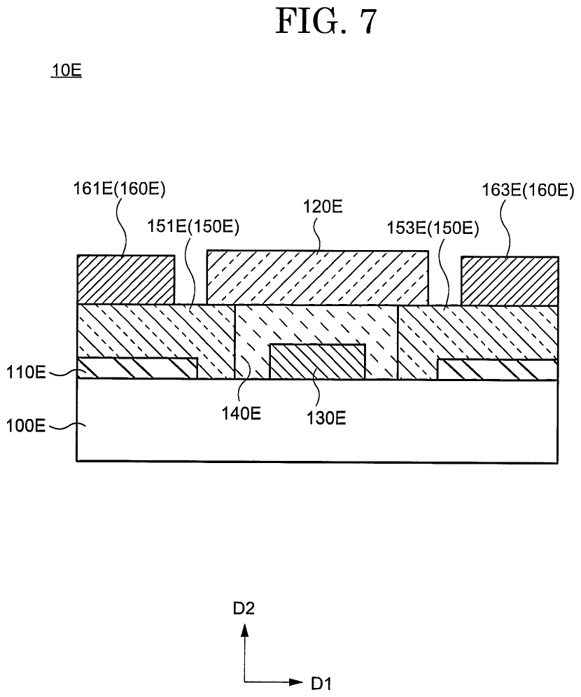

Referring to FIG. 7, a semiconductor device 10E according to a sixth embodiment of the present disclosure will be described. The semiconductor device 10E is similar to the semiconductor device 10D according to the fifth embodiment. Differences from the semiconductor device 10D in a configuration of the semiconductor device 10E will be mainly described in the following explanation. In the case of describing the same configuration as the above embodiment in the following explanation, with reference to FIG. 1, the letter “E” is added after the reference symbols shown in FIG. 1.

### [6-1. Configuration of Semiconductor Device 10E]

As shown in FIG. 7, an oriented insulating layer 110E is arranged between a substrate 100E and a second gallium nitride layer 150E, and is in contact with the second gallium nitride layer 150E in the present embodiment. The second gallium nitride layer 150E is in contact with a first gallium nitride layer 120E from below the first gallium nitride layer 120E. A gate electrode 130E has a crystalline orientation similar to that of the gate electrode 130D of the fifth embodiment. On the other hand, unlike the semiconductor device 10D according to the fifth embodiment, the oriented insulating layer 110E is not arranged in a region where the gate electrode 130E and a gate insulating layer 140E are arranged, and the gate electrode 130E is in contact with the substrate 100E. In the present embodiment, the gate insulating layer 140E arranged on the gate electrode 130E is in contact with the substrate 100E, and the second gallium nitride layer 150E arranged on the oriented insulating layer 110E is in contact with the substrate 100E.

Although FIG. 7 shows a configuration in which the second gallium nitride layer 150E covers a patterned end portion of the oriented insulating layer 110E, the configuration is not limited to this configuration. The patterned end portion may be located near a border between the gate insulating layer 140E and the second gallium nitride layer 150E, or may be covered with the gate insulating layer 140E. Instead of the oriented insulating layer 110E, a crystal-oriented conductive layer formed in the same layer as the gate electrode 130E may be arranged.

### 7. Seventh Embodiment

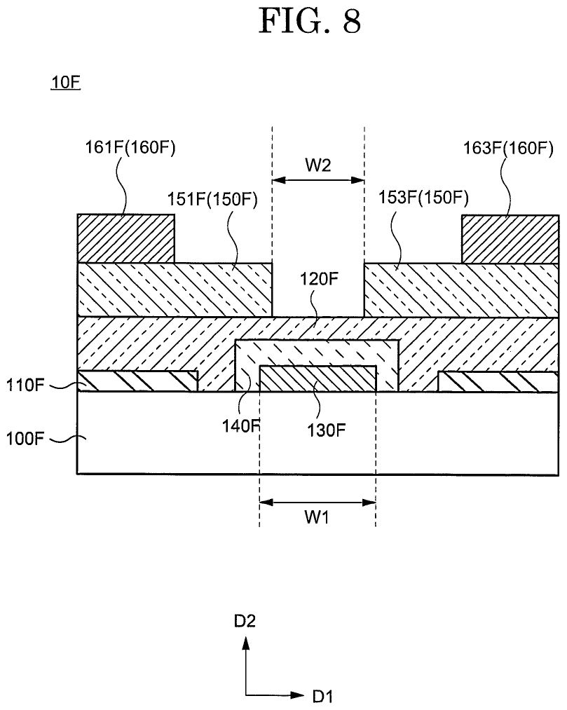

Referring to FIG. 8, a semiconductor device 10F according to a seventh embodiment of the present disclosure will be described. The semiconductor device 10F is similar to the semiconductor device 10E according to the seventh embodiment. Differences from the semiconductor device 10E in a configuration of the semiconductor device 10F will be mainly described in the following explanation. In the case of describing the same configuration as the above embodiment in the following explanation, with reference to FIG. 1, the letter “F” is added after the reference symbols shown in FIG. 1.

### [7-1. Configuration of Semiconductor Device 10F]

As shown in FIG. 8, a second gallium nitride layer 150F and an electrode 160F are arranged on a first gallium nitride layer 120F. The second gallium nitride layer 150F is in contact with the first gallium nitride layer 120F. The first gallium nitride layer 120F covers an oriented insulating layer 110F and a gate insulating layer 140F. The oriented insulating layer 110F is in contact with the first gallium nitride layer 120F between the first gallium nitride layer 120F and a substrate 100F in a region overlapping the second gallium nitride layer 150F in plan view.

In FIG. 8, although a configuration is shown in which a width W1 of a gate electrode 130F is larger than a distance W2 between a source-side second gallium nitride layer 151F and a drain-side second gallium nitride layer 153F in the direction D1, the configuration is not limited to this configuration. The width W1 of the gate electrode 130F may be smaller than the distance W2 between the source-side second gallium nitride layer 151F and the drain-side second gallium nitride layer 153F, and the source-side second gallium nitride layer 151F and the drain-side second gallium nitride layer 153F may be continuously connected to each other.

### [7-2. Method for Manufacturing Semiconductor Device 10F]

After the oriented insulating layer 110F, the gate electrode 130F, and the gate insulating layer 140F are patterned, the first gallium nitride layer 120F and the second gallium nitride layer 150F are continuously formed. Subsequently, the second gallium nitride layers 150F are patterned. Then, the electrode 160F is formed on the patterned second gallium nitride layer 150F.

A contacting area of the second gallium nitride layer 150F and the first gallium nitride layer 120F can be increased by arranging the second gallium nitride layer 150F on the first gallium nitride layer 120F as described above. As a result, a current concentration in a junction region of these layers can be suppressed. Further, good crystallinity can be obtained for the first gallium nitride layer 120F and the second gallium nitride layer 150F by continuously forming the first gallium nitride layer 120F and the second gallium nitride layer 150F on the oriented insulating layer 110F and the gate insulating layer 140F.

### 8. Eighth Embodiment

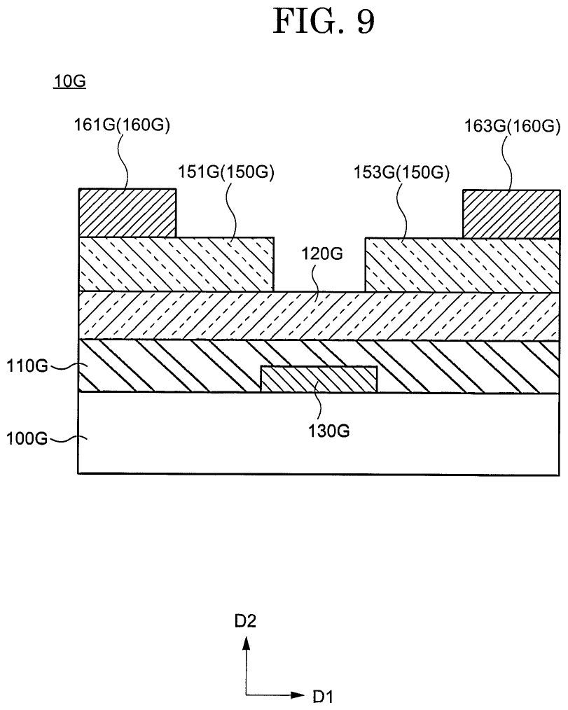

Referring to FIG. 9, a semiconductor device 10G according to an eighth embodiment of the present disclosure will be described. The semiconductor device 10G is similar to the semiconductor device 10F according to the eighth embodiment. Differences from the semiconductor device 10F in a configuration of the semiconductor device 10G will be mainly described in the following explanation. In the case of describing the same configuration as the above embodiment in the following explanation, with reference to FIG. 1, the letter “G” is added after the reference symbols shown in FIG. 1.

### [8-1. Configuration of Semiconductor Device 10G]

An oriented insulating layer 110G covers a gate electrode 130G as shown in FIG. 9. A first gallium nitride layer 120G is arranged on the oriented insulating layer 110G. That is, the oriented insulating layer 110G functions as a gate insulating layer in the present embodiment. The oriented insulating layer 110G having a function as the gate insulating layer and the first gallium nitride layer 120G are in contact with each other in a region overlapping a second gallium nitride layer 150G in a plan view as shown in FIG. 9. Similarly, the first gallium nitride layer 120G and the second gallium nitride layer 150G are in contact with each other in the region described above.

### [8-2. Method for Manufacturing Semiconductor Device 10G]

The oriented insulating layer 110G, the first gallium nitride layer 120G, and the second gallium nitride layer 150G are continuously formed after the gate electrode 130G is patterned. Subsequently, the second gallium nitride layer 150G is patterned. Then, an electrode 160G is formed on the patterned second gallium nitride layer 150G.

According to the configuration of the present embodiment, the same effects as those of the seventh embodiment can be obtained.

### [8-3. Modification of Semiconductor Device 10G]

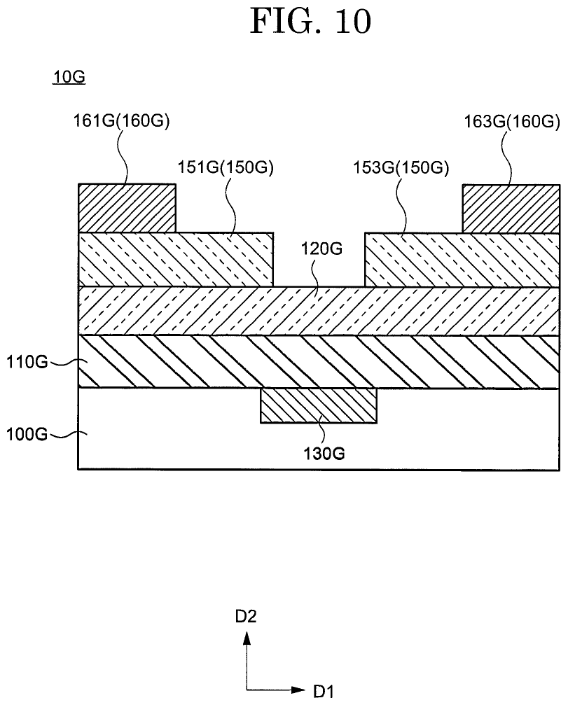

As shown in FIG. 10, the gate electrode 130G may be embedded in a substrate 100G. That is, a recess is formed in the substrate 100G, and the gate electrode 130G is embedded in the recess. Although an upper surface of the substrate 100G and an upper surface of the gate electrode 130G coincide with each other in the direction D2 in FIG. 10, the upper surfaces of both may not coincide with each other in the direction D2.

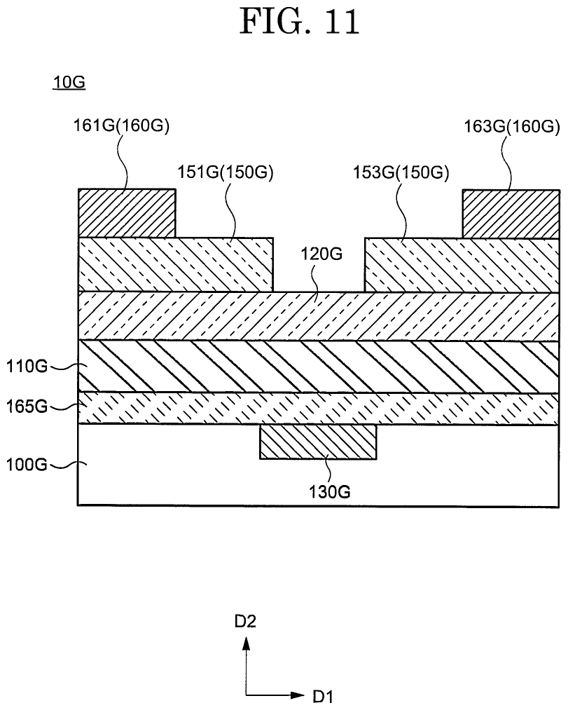

A planarization layer 165G may be arranged between the substrate 100G and the oriented insulating layer 110G as shown in FIG. 11. In this case, even if positions of the upper surface of the substrate 100G and the upper surface of the gate electrode 130G in the direction D2 do not coincide with each other, a surface (upper surface of the planarization layer 165G) on which the oriented insulating layer 110G is formed can be provided. Therefore, good orientation of the oriented insulating layers 110G can be obtained.

### 9. Ninth Embodiment

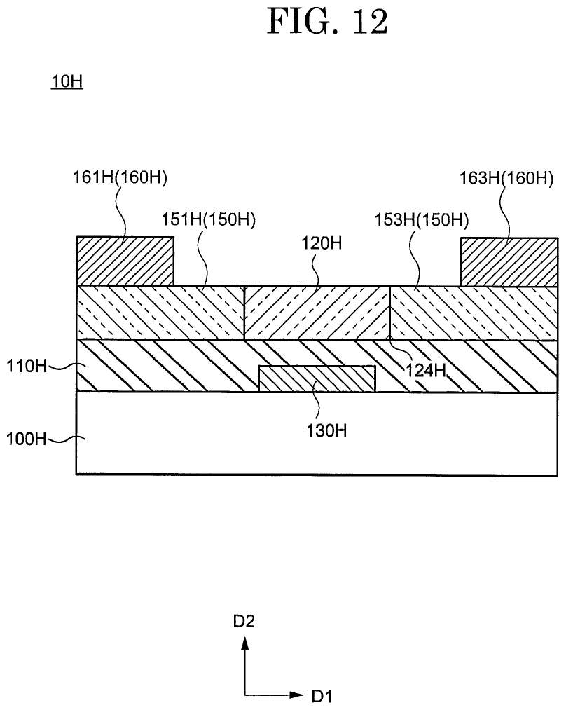

A semiconductor device 10H according to a ninth embodiment of the present disclosure will be described referring to FIG. 12. The semiconductor device 10H is similar to the semiconductor device 10G according to the ninth embodiment. Differences from the semiconductor device 10G in a configuration of the semiconductor device 10H will be mainly described in the following explanation. In the case of describing the same configuration as the above embodiment in the following explanation, with reference to FIG. 1, the letter “H” is added after the reference symbols shown in FIG. 1.

### [9-1. Configuration of Semiconductor Device 10H]

As shown in FIG. 12, a second gallium nitride layer 150H is horizontally (direction D1) adjoined to a first gallium nitride layer 120H. In other words, each of the first gallium nitride layer 120H and the second gallium nitride layer 150H is in contact with an oriented insulating layer 110H. The second gallium nitride layer 150H is in contact with the first gallium nitride layer 120H at a sidewall of the first gallium nitride layer 120H. When a predetermined voltage is supplied to a gate electrode 130H, carriers are generated in the first gallium nitride layer 120H (channel is formed) in a vicinity of an interface between the first gallium nitride layer 120H and the oriented insulating layer 110H. That is, the second gallium nitride layer 150H is in contact with the first gallium nitride layer 120H in a vicinity (124H) of a region where the carriers are formed in the first gallium nitride layer 120H.

Since the second gallium nitride layer 150H is in contact with the first gallium nitride layer 120H in the region where the carriers are formed (region where the channel is formed) as described above, resistivity of a current path from an electrode 160H to the channel formed in the first gallium nitride layer 120H can be reduced.

### [9-2. Modification of Semiconductor Device 10H]

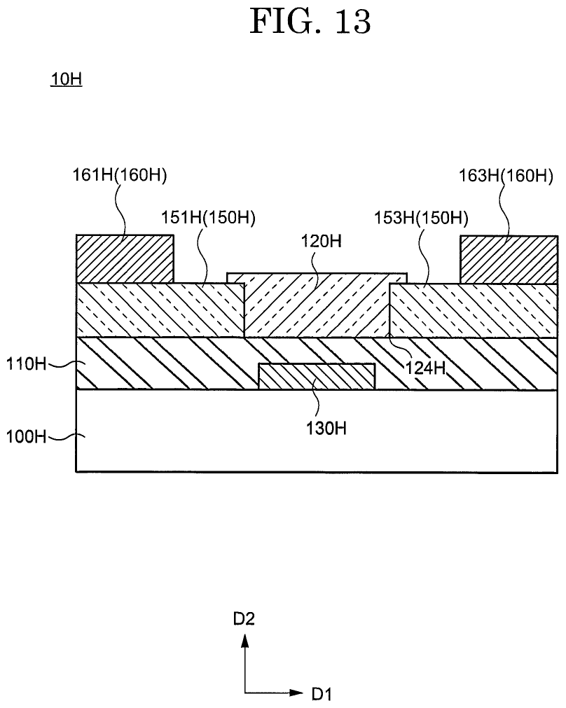

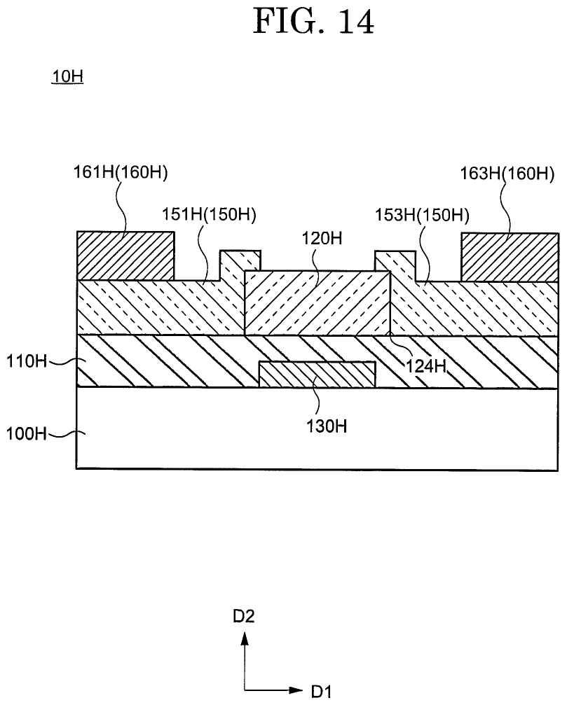

FIG. 12 shows a configuration in which positions of an upper surface of the first gallium nitride layer 120H and an upper surface of the second gallium nitride layer 150H coincide with each other in the direction D2. However, the configuration is not limited to this configuration. For example, the structure shown in FIG. 13 can be obtained by forming and patterning the second gallium nitride layer 150H first, and forming the first gallium nitride layer 120H later. On the other hand, the structure shown in FIG. 14 can be obtained by forming and patterning the first gallium nitride layer 120H first, and forming the second gallium nitride layer 150H later. The resistivity of the current path from the electrode 160H to the channel formed in the first gallium nitride layer 120H can be reduced in either configuration as in the configuration of FIG. 12.

### 10. Tenth Embodiment

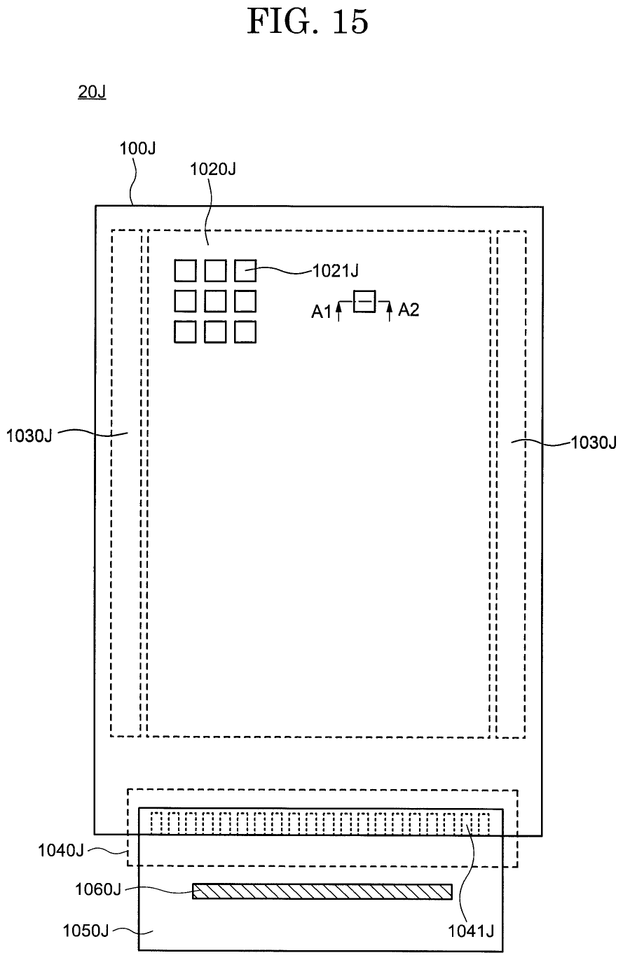

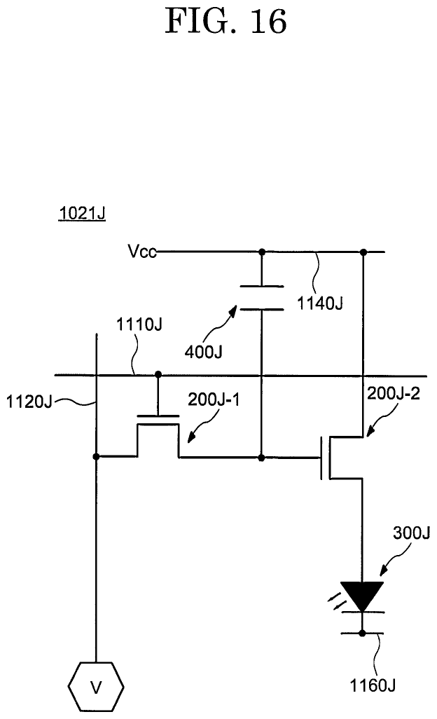

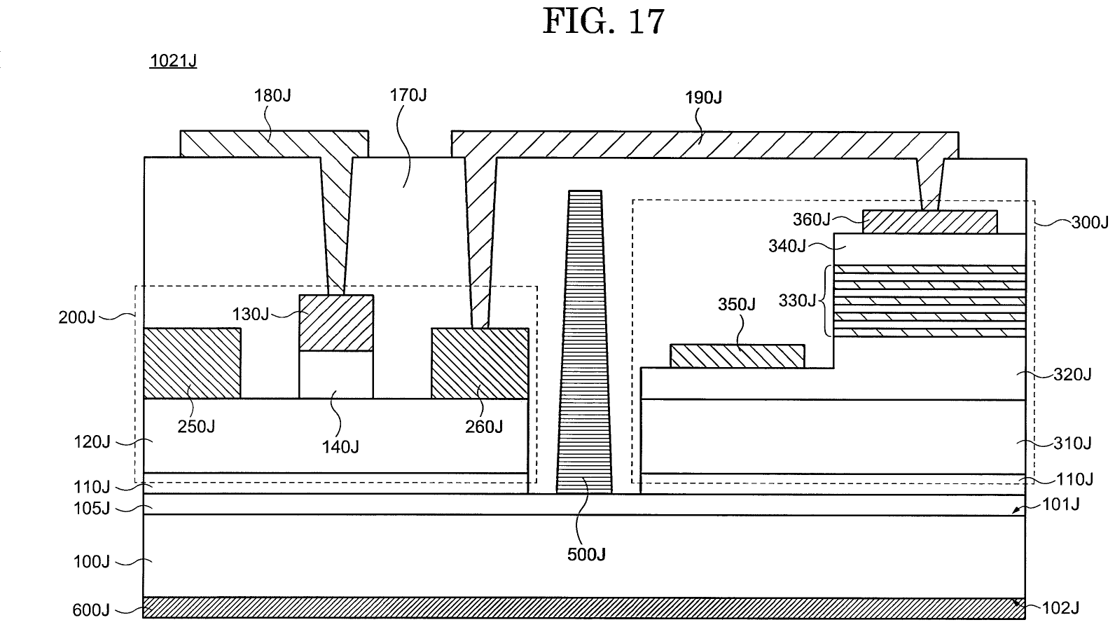

Referring to FIG. 15 to FIG. 17, a display device 20J according to a tenth embodiment of the present disclosure will be described. FIG. 15 is a schematic diagram showing a configuration of a display device according to an embodiment of the present invention. FIG. 16 is a circuit diagram (pixel circuit) of a pixel of a display device according to an embodiment of the present invention. FIG. 17 is a cross-sectional view of a pixel of a display device according to an embodiment of the present invention.

### [10-1. Outline of Display Device 20J Configuration]

FIG. 15 is a schematic diagram showing a configuration of the display device 20J according to an embodiment of the present disclosure. The display device 20J includes a display unit 1020J, a drive circuit unit 1030J, and a terminal unit 1040J on a substrate 100J. The drive circuit unit 1030J is arranged around the display unit 1020J and controls the display unit 1020J. The drive circuit unit 1030J includes, for example, a scan drive circuit and the like. The terminal unit 1040J is arranged at an end portion of the substrate 100J, and supplies an external signal and power to the display device 20J. The terminal unit 1040J includes, for example, a terminal 1041J. The terminal 1041J is connected to a flexible printed circuit board 1050J. A driver IC 1060J is arranged on the flexible printed circuit board 1050J.

The display unit 1020J may display an image or a video, and includes a plurality of pixels 1021J arranged in a matrix. However, an arrangement of the plurality of pixels 1021J are not limited to the matrix. For example, the plurality of pixels 1021J may be arranged in a staggered manner.

### [10-2. Configuration of Pixel 1021J]

FIG. 16 is a circuit diagram (pixel circuit) of the pixel 1021J of the display device 20J according to an embodiment of the present disclosure. The pixel 1021J includes a first transistor 200J-1, a second transistor 200J-2, a light-emitting diode 300J, and a capacitive element 400J.

The first transistor 200J-1 functions as a selection transistor. That is, a conduction of the first transistor 200J-1 is controlled by a scanning line 1110J. In the first transistor 200J-1, a gate, a source, and a drain are electrically connected to the scanning line 1110J, a signal line 1120J, and a gate of the second transistor 200J-2, respectively.

The second transistor 200J-2 functions as a driving transistor. That is, the second transistor 200J-2 controls emission brightness of the light-emitting diode 300J. In the second transistor 200J-2, the gate, a source, and a drain are electrically connected to the drain of the first transistor 200J-1, a drive power supply line 1140J, and an anode (p-type electrode) of the light-emitting diode 300J, respectively.

One of the capacitance electrodes of the capacitive element 400J is electrically connected to the gate of the second transistor 200J-2 and the drain of the first transistor 200J-1. The other capacitance electrode of the capacitive element 400J is electrically connected to the drive power supply line 1140J.

The anode of the light-emitting diode 300J is connected to the drain of the second transistor 200J-2. A cathode (n-type electrode) of the light-emitting diode 300J is connected to a reference power supply line 1160J.

### [10-3. Cross-section of Display Device 20J]

A layer configuration of the pixel 1021J will be described referring to FIG. 17. The first transistor 200J-1 and the second transistor 200J-2 are not particularly distinguished from each other and are explained as a transistor 200J in the explanation of FIG. 17.

FIG. 17 is a cross-sectional view of the pixel 1021J taken along a line A1-A2 shown in FIG. 15. As shown in FIG. 17, the display device 20J includes the substrate 100J, an underlayer 105J, an oriented insulating layer 110J, the transistor 200J, the light-emitting diode 300J, a light-shielding wall 500J, a light-shielding layer 600J, an interlayer film 170J, a conductive layer 180J, and a transparent conductive layer 190J. The underlayer 105J, the oriented insulating layer 110J, the transistor 200J, the light-emitting diode 300J, the light-shielding wall 500J, the interlayer film 170J, the conductive layer 180J, and the transparent conductive layer 190J are arranged on a first surface 101J side of the substrate 100J. The light-shielding layer 600J is arranged on a second surface 102J side of the substrate 100J opposite to the first surface 101J.

The substrate 100J is a support substrate for the transistor 200J and the light-emitting diode 300J. As the substrate 100J, an amorphous glass substrate or the like can be used as described above.

The underlayer 105J is arranged on the substrate 100J. The underlayer 105J may prevent impurities from the substrate 100J or impurities from the outside (for example, water, sodium, or the like) from diffusing. For example, a silicon nitride layer or a stack of a silicon oxide layer and a silicon nitride layer may be used as the underlayer 105J.

The oriented insulating layer 110J is arranged on the underlying layer 105J. Crystallinity of a first gallium nitride layer 120J of the transistor 200J formed on the oriented insulating layer 110J can be improved, and crystallinity of a gallium nitride layer 310J of the light-emitting diode 300J formed on the oriented insulating layer 110J can be improved by arranging the oriented insulating layer 110J. The first gallium nitride layer 120J and the gallium nitride layer 310J are formed in the same layer and have the same film thickness and physical properties.

In the case where the oriented insulating layer 110J includes a nitrogen compound (for example, titanium nitride or aluminum nitride), the underlayer 105J may not be arranged. Since nitrogen contained in the nitrogen compound described above has a large electronegativity, it is possible to trap the impurities contained in the substrate 100J.

The transistor 200J includes the first gallium nitride layer 120J, a gate electrode 130J, a gate insulating layer 140J, a source electrode 250J, and a drain electrode 260J. For example, the source electrode 250J corresponds to the source-side second gallium nitride layer 151 and the source-side electrode 161 in FIG. 1. For example, the drain electrode 260J corresponds to the drain-side second gallium nitride layer 153 and the drain-side electrode 163 in FIG. 1.

The first gallium nitride layer 120J is arranged on the oriented insulating layer 110J. Since the first gallium nitride layer 120J is in contact with the oriented insulating layer 110J as described above, crystal growth of the first gallium nitride layer 120J is controlled by the oriented insulating layer 110J. Consequently, the first gallium nitride layer 120J is c-axis oriented with respect to the substrate 100J.

Although the transistor 200J is a so-called MOS transistor, the transistor 200J may be a HEMT (High Electron Mobility Transistor).

The light-emitting diode 300J is arranged on the oriented insulating layer 110J. The light-emitting diode 300J includes the gallium nitride layer 310J, an n-type semiconductor layer 320J, a light-emitting layer 330J, a p-type semiconductor layer 340J, an n-type electrode 350J, and a p-type electrode 360J.

The gallium nitride layer 310J is arranged on the oriented insulating layer 110J. For example, a gallium nitride layer or the like is used as the gallium nitride layer 310J. Since the gallium nitride layer 310J is in contact with the oriented insulating layer 110J, crystal growth of the gallium nitride layer 310J is controlled by the oriented insulating layer 110J. Consequently, the gallium nitride layer 310J is c-axis oriented with respect to the substrate 100J.

The n-type semiconductor layer 320J is arranged on the gallium nitride layer 310J. For example, a silicon-doped gallium nitride layer or the like is used as the n-type semiconductor layer 320J.

The light-emitting layer 330J is arranged on the n-type semiconducting layer 320J. For example, a stack in which an indium-gallium nitride layer and a gallium nitride layer are alternately stacked is used as the light-emitting layer 330J.

The p-type semiconducting layer 340J is arranged on the light-emitting layer 330J. For example, a magnesium-doped gallium nitride layer is used as the p-type semiconducting layer 340J.

The n-type electrode 350J and the p-type electrode 360J are respectively arranged on the n-type semiconductor layer 320J and the p-type semiconductor layer 340J. For example, a metal such as indium is used as the n-type electrode 350J. For example, a metal such as palladium or gold is used as the p-type electrode 360J.

Although the light-emitting diode 300J may be a so-called micro LED or a mini LED, the light-emitting diode 300J is not limited to those. The micro LED is a LED having a size of 100 micrometers or less on one side. The mini LED is a LED having a size of 100 micrometers or more on one side.

Although not shown in the drawings, a protective layer may be arranged to cover the transistor 200J or the light-emitting diode 300J as needed. A silicon nitride layer or a stacked layer of a silicon oxide layer and a silicon nitride layer may be used as the protective layer.

The light-shielding wall 500J is arranged between the transistor 200J and the light-emitting diode 300J. The light-shielding wall 500J can block light emitted from the light-emitting diode 300J and prevent the transistor 200J from being irradiated with light. For example, an acrylic resin (resin black) to which carbon is added can be used as the light-shielding wall 500J.

The light-shielding layer 600J is arranged on the second surface 102J of the substrate 100J. The light-shielding layer 600J can block light from the outside and prevent the transistor 200J from being irradiated with light. For example, an acrylic resin (resin black) to which carbon is added may be used as the light-shielding 600J.

The interlayer film 170J is arranged so as to cover the transistor 200J, the light-emitting diode 300J, and the light-shielding wall 500J. The interlayer film 170J can planarize irregularities formed by the transistor 200J, the light-emitting diode 300J, and the light-shielding wall 500J. For example, an organic insulating film such as an acryl resin film or a polyimide resin film is used as the interlayer film 170J. The interlayer film 170J may be a single layer or a stacked layer. In the case where the interlayer film 170J is a stacked layer, the interlayer film 170J may include not only an organic insulating layer but also an inorganic insulating layer such as a silicon oxide layer or a silicon nitride layer.

The conductive layer 180J and the transparent conductive layer 190J are arranged on the interlayer film 170J. The conductive layer 180J is electrically connected to the gate electrode 130J via an opening arranged in the interlayer film 170J. The transparent conductive layer 190J electrically connects the drain electrode 260J and the p-type electrode 360J via an opening arranged in the interlayer film 170J. The light emitted from the light-emitting layer 330J of the light-emitting diode 300J passes through the transparent conductive layer 190J and is emitted to the outside. For example, a stacked layer of aluminium and titanium (for example, Ti/Al/Ti) can be used as the conductive layer 180J. For example, a transparent conductive layer such as an indium-tin-oxide (ITO) film or an indium-zinc-oxide (IZO) film can be used as the transparent conductive layer 190J.

Each of the embodiments described above as the embodiment of the present invention can be appropriately combined as long as they are not mutually contradictory. The addition, deletion, or design change of components as appropriate, or addition, omission or changes in conditions of processes by those skilled in the art based on each embodiment are also included in the scope of the present invention as long as they are provided with the gist of the present disclosure.

It is understood that, even if the advantageous effect is different from those provided by each of the above-described embodiments, the advantageous effect obvious from the description in the specification or easily predicted by persons ordinarily skilled in the art is apparently derived from the present disclosure.

What is claimed is:

1. A semiconductor device comprising:
an amorphous glass substrate;
an oriented insulating layer arranged on the amorphous glass substrate and having a crystal orientation;
a first gallium nitride layer arranged on the oriented insulating layer and in contact with the oriented insulating layer, the first gallium nitride layer being a first conductivity type;
a gate electrode opposed to the first gallium nitride layer; and
a gate insulating layer between the first gallium nitride layer and the gate electrode.

2. The semiconductor device according to claim 1
wherein
the oriented insulating layer has a plane with 6-fold rotational symmetry.

3. The semiconductor device according to claim 2
wherein
the oriented insulating layer has a (0001) plane in a hexagonal close-packed structure or a (111) plane in a face-centered cubic structure.

4. The semiconductor device according to claim 1
wherein
the oriented insulating layer includes aluminum nitride, gallium oxide, titanium nitride, or titanium oxide.

5. The semiconductor device according to claim 1
wherein
the gate electrode is arranged on the first gallium nitride layer.

6. The semiconductor device according to claim 1
further comprising
a second gallium nitride layer having higher conductivity than the first gallium nitride layer, the second gallium nitride layer being a second conductivity type,
wherein
the second gallium nitride layer is in contact with the first gallium nitride layer from above the first gallium nitride layer.

7. The semiconductor device according to claim 1
further comprising
a second gallium nitride layer having higher conductivity than the first gallium nitride layer, the second gallium nitride layer being a second conductivity type,
wherein
the first gallium nitride layer is in contact with the second gallium nitride layer from above the second gallium nitride layer in a first region, and
the first gallium nitride layer is in contact with the oriented insulating layer exposed from the second gallium nitride layer in a second region different from the first region.

8. The semiconductor device according to claim 7
wherein second gallium nitride layer includes a source-side second gallium nitride layer and a drain-side second gallium nitride layer, and
a width of the gate electrode is larger than a distance between the source-side second gallium nitride layer and the drain-side second gallium nitride layer in an arbitrary first direction on a main surface of the amorphous glass substrate.

9. The semiconductor device according to claim 1
further comprising
a second gallium nitride layer having higher conductivity than the first gallium nitride layer, the second gallium nitride layer being a second conductivity type,
wherein
the gate insulating layer is in contact with the first gallium nitride layer from above the first gallium nitride layer, and
a part of the second gallium nitride layer is in contact with the gate insulating layer from above the gate insulating layer.

10. A semiconductor device comprising:
an amorphous glass substrate;
a gate electrode arranged on the amorphous glass substrate;
a gate insulating layer arranged on the gate electrode and having a crystal orientation; and
a first gallium nitride layer arranged on the gate insulating layer and in contact with the gate insulating layer, the first gallium nitride layer being a first conductivity type.

11. The semiconductor device according to claim 10
wherein
the gate insulating layer has a plane with 6-fold rotational symmetry.

12. The semiconductor device according to claim 11
wherein
the gate insulating layer has a (0001) plane in a hexagonal close-packed structure or a (111) plane in a face-centered cubic structure.

13. The semiconductor device according to claim 10
wherein
the gate insulating layer includes aluminum nitride, gallium oxide, titanium nitride, or titanium oxide.

14. The semiconductor device according to claim 10
further comprising
an oriented insulating layer arranged between the amorphous glass substrate and the gate electrode, and having a crystal orientation,
wherein
the gate electrode and the gate insulating layer have the same crystal orientation as the oriented insulating layer.

15. The semiconductor device according to claim 14
further comprising
a second gallium nitride layer having higher conductivity than the first gallium nitride layer, the second gallium nitride layer being a second conductivity type,
wherein
the second gallium nitride layer is in contact with the oriented insulating layer from above the oriented insulating layer and is in contact with the first gallium nitride layer from below the first gallium nitride layer.

16. The semiconductor device according to claim 10
further comprising
a second gallium nitride layer having higher conductivity than the first gallium nitride layer, the second gallium nitride layer being a second conductivity type, and
an oriented insulating layer having a crystal orientation provided between the amorphous glass substrate and the second gallium nitride layer, the oriented insulating layer being in contact with the second gallium nitride layer,
wherein
the gate electrode has a crystal orientation and is in contact with the gate insulating layer, and
the second gallium nitride layer is in contact with the first gallium nitride layer from below the first gallium nitride layer.

17. The semiconductor device according to claim 10
further comprising
a second gallium nitride layer having higher conductivity than the first gallium nitride layer, the second gallium nitride layer being a second conductivity type, and
an oriented insulating layer having a crystal orientation in contact with the first gallium nitride layer between the amorphous glass substrate and the first gallium nitride layer in a region overlapping the second gallium nitride layer in a plan view,
wherein
the second gallium nitride layer is in contact with the first gallium nitride layer from above the first gallium nitride layer.

18. The semiconductor device according to claim 10
further comprising
a second gallium nitride layer having higher conductivity than the first gallium nitride layer, the second gallium nitride layer being a second conductivity type,
wherein
the gate insulating layer is in contact with the first gallium nitride layer, and the first gallium nitride layer is in contact with the second gallium nitride layer in a region overlapping the second gallium nitride layer in a plan view.

19. The semiconductor device according to claim 10
further comprising
a second gallium nitride layer having higher conductivity than the first gallium nitride layer, the second gallium nitride layer being a second conductivity type,
wherein
the second gallium nitride layer is in contact with the gate insulating layer at a position adjacent to the first gallium nitride layer in an arbitrary first direction on a main surface of the amorphous glass substrate.
